(19) United States
(12) Patent Application Publication
(10) Pub. No.: US 2026/0343736 A1
(43) Pub. Date: Oct. 29, 2026

(54) CHIP-ON-FILM, DISPLAY MODULE, AND DISPLAY DEVICE

(71) Applicant: BEIJING SHIYAN TECHNOLOGY CO., LTD., Beijing (CN)

(72) Inventors: Meili Wang, Beijing (CN); Lei Wang, Beijing (CN); Wei Sun, Beijing (CN); Zhongyuan Wu, Beijing (CN); Xue Dong, Beijing (CN); Wenchao Han, Beijing (CN); Shuilang Dong, Beijing (CN)

(73) Assignee: BEIJING SHIYAN TECHNOLOGY CO., LTD., Beijing (CN)

(21) Appl. No.: 19/731,863

(22) Filed: Jul. 6, 2026

Related U.S. Application Data
(63) Continuation-in-part of application No. 18/580,211, filed on Feb. 20, 2023.

(30) Foreign Application Priority Data
Mar. 2, 2022 (CN) 202210204960.4

(51) Int. Cl. H05K 1/02

(52) U.S. Cl. CPC H05K 1/0298; H05K 2201/10128

(57) ABSTRACT

Disclosed are a chip-on-film, a display module and a display device. The chip-on-film includes: a substrate; one or more wiring layers, the wiring layers being stacked perpendicular to the substrate, each wiring layer including a plurality of through leads spaced apart from each other; and a lead layer disposed on a side of all of the wiring layers facing away from the substrate, the lead layer including a plurality of third leads located in a chip bonding region, the plurality of third leads being arranged in an array along a first direction and a second direction, respectively; the third leads are connected to a panel bonding region via the through leads, and orthographic projections of the through leads on the substrate overlap with that of lead gaps in the chip bonding region, each lead gap being a gap between two adjacent third leads arranged along the first direction.

### CROSS-REFERENCE TO RELEVANT APPLICATIONS

The present application is a continuation-in-part application of US18/580,211, which claims the priority of the Chinese patent application filed on Mar. 02^{nd}, 2022 before the Chinese Patent Office with the application number of 202210204960.4 and the title of “DISPLAY DEVICE AND PREPARATION METHOD THEREFOR”, which is incorporated herein in its entirety by reference.

### TECHNICAL FIELD

The present application relates to the field of display technology, and in particular, to a chip-on-film, a display module, and a display device.

### BACKGROUND

With the emergence of new display products such as naked-eye 3D and micro LED, the resolution of display panels is becoming increasingly higher, and the demand for information volume is continually growing. However, the number of channels of a conventional chip-on-film (COF) is often lower than 2000, making it difficult to meet the requirements of high-resolution display panels.

### SUMMARY

The present application provides a chip-on-film, the chip-on-film including a chip bonding region and a panel bonding region spaced apart from each other, the chip-on-film including:
a substrate;
one or more wiring layers, the plurality of wiring layers being stacked in a direction perpendicular to the substrate, each wiring layer including a plurality of through leads spaced apart from each other; and
a lead layer disposed on a side of all of the wiring layers facing away from the substrate, the lead layer including a plurality of third leads located in the chip bonding region, the plurality of third leads being arranged in an array along a first direction and a second direction, respectively, the first direction and the second direction intersecting each other;
wherein the third leads are connected to the panel bonding region via the through leads, and orthographic projections of the through leads on the substrate overlap with orthographic projections of the lead gaps in the chip bonding region on the substrate, each lead gap being a gap between two adjacent third leads arranged along the first direction.

In some embodiments, the plurality of third leads are divided into a plurality of lead rows, each lead row including a plurality of the third leads arranged along the first direction, the plurality of lead rows being arranged along the second direction;
the plurality of lead rows include a first lead row and a second lead row, the second lead row being located between the first lead row and the panel bonding region, and in the orthographic projection on the substrate, the through leads connected to the third leads in the first lead row overlap with lead gaps in the second lead row.

In some embodiments, the plurality of third leads are divided into a plurality of lead rows, each lead row including a plurality of the third leads arranged along the first direction, the plurality of lead rows being arranged along the second direction, and the third leads in two adjacent lead rows are aligned along the first direction.

In some embodiments, the plurality of third leads arranged along the second direction include a first sub-lead and a second sub-lead, the second sub-lead being located between the first sub-lead and the panel bonding region, the through lead connected to the first sub-lead being a first through lead, and the through lead connected to the second sub-lead being a second through lead;
in the orthographic projection on the substrate, the lead gaps overlapping with the second through lead also overlap with the first through lead.

In some embodiments, a plurality of lead gaps in a same lead row include a first lead gap and a second lead gap, and in the orthographic projection on the substrate, a number of the through leads overlapping with the first lead gap is equal to a number of the through leads overlapping with the second lead gap.

In some embodiments, the plurality of third leads are divided into a plurality of lead rows, each lead row including a plurality of the third leads arranged along the first direction, the plurality of lead rows being arranged along the second direction, and the third leads in two adjacent lead rows are staggered along the first direction.

In some embodiments, the plurality of lead rows include a third lead row and a fourth lead row, the fourth lead row being located between the third lead row and the panel bonding region;
the plurality of through leads include a third through lead and a fourth through lead, and in the orthographic projection on the substrate, the third through lead and the fourth through lead overlap with a same lead gap in the third lead row, and the third through lead and the fourth through lead respectively overlap with different lead gaps in the fourth lead row.

In some embodiments, a plurality of lead gaps in a same lead row include a third lead gap and a fourth lead gap, and in the orthographic projection on the substrate, a number of the through leads overlapping with the third lead gap is less than or equal to a number of the through leads overlapping with the fourth lead gap.

In some embodiments, in the orthographic projection on the substrate, the number of the through leads overlapping with the third lead gap is less than the number of the through leads overlapping with the fourth lead gap; and
the wiring layer further includes a dummy lead, the dummy lead being disposed spaced apart from the through leads and the third leads, respectively, and in the orthographic projection on the substrate, the dummy lead overlaps with the third lead gap, and a total number of the dummy lead and the through leads overlapping with the third lead gap is equal to the number of the through leads overlapping with the fourth lead gap.

In some embodiments, the chip-on-film includes a plurality of the wiring layers, and in the orthographic projection on the substrate, two adjacent through leads that overlap with a same lead gap are disposed in different layers.

In some embodiments, in the orthographic projection on the substrate, the lead gaps in both the first lead row and the second lead row overlap with the through leads, and a number of the through leads overlapping with the lead gaps in the first lead row is less than a number of the through leads overlapping with the lead gaps in the second lead row.

In some embodiments, along the first direction, a width of the lead gaps in the second lead row is greater than or equal to a width of the lead gaps in the first lead row.

In some embodiments, the lead layer further includes a bypass lead, the bypass lead being disposed spaced apart from the third leads, and an orthographic projection of the bypass lead on the substrate does not overlap with the lead gaps.

In some embodiments, the through lead includes third line segments and fourth line segments alternately connected, the third line segments extending along the second direction, and an extension direction of the fourth line segments intersecting both the first direction and the second direction, respectively.

In some embodiments, in a case where two ends of the third line segment are each connected to one fourth line segment, the two fourth line segments connected to the same third line segment have different extension directions.

In some embodiments, a thickness of the lead layer is greater than a thickness of the wiring layer.

The present application provides a display module, including:
a display panel, the display panel including a non-display area, the non-display area including a bonding portion; and
the chip-on-film as provided by any one of the embodiments, the panel bonding region of the chip-on-film being bonded to the bonding portion.

In some embodiments, the chip-on-film further includes a driving board bonding region, the driving board bonding region and the panel bonding region being disposed opposite to each other along the second direction on two sides of the chip bonding region;
the display module further includes at least one of:
a chip, bonded at least to the third leads in the chip bonding region; and
a driving board, bonded to the driving board bonding region.

In some embodiments, the driving board includes: a flexible circuit board and a rigid circuit board, the flexible circuit board being connected between the driving board bonding region and the rigid circuit board.

The present application provides a display device, including the chip-on-film as provided by any one of the embodiments, or including the display module as provided by any one of the embodiments.

The above description is merely an overview of the technical solutions of the present application. In order to understand the technical means of the present application more clearly so that they can be implemented according to the content of the specification, and in order to make the above and other objects, features and advantages of the present application more apparent and understandable, specific embodiments of the present application are set forth below.

### BRIEF DESCRIPTION OF THE DRAWINGS

In order to more clearly illustrate the technical solutions of the embodiments of the present application or the related art, the drawings required for use in the description of the embodiments or the related art will be briefly introduced below. Apparently, the drawings in the following description are some embodiments of the present application, and for a person of ordinary skill in the art, other drawings can also be obtained based on these drawings without exerting creative effort. It should be noted that, the accompanying drawings described below are not drawn to scale, are merely exemplary, and should not be construed as limiting the present application.

FIG. 1 is a schematic structural diagram of a chip packaging unit according to an embodiment of the present application;

FIG. 2 is a schematic structural diagram of a display panel according to an embodiment of the present application;

FIG. 3 is a schematic structural diagram after FIG. 1 and FIG. 2 are bonded;

FIG. 4 is a schematic structural diagram after the rigid substrate in FIG. 3 are stripped;

FIG. 5, FIG. 6a, FIG. 6b and FIG. 7 are schematic structural diagrams after four types of chip packaging units according to the embodiments of the present application are bent;

FIG. 8 is a schematic structural diagram of another chip packaging unit according to an embodiment of the present application;

FIG. 9 is a schematic structural diagram of a chip packaging unit of single-layer trace according to an embodiment of the present application;

FIG. 10 is a cross-sectional view along the direction of CC1 of FIG. 9;

FIG. 11 is a cross-sectional view along the direction of C2C3 of FIG. 9;

FIG. 12 is a schematic structural diagram of a first lead-wire layer according to an embodiment of the present application;

FIG. 13 is a schematic structural diagram of a lead layer according to an embodiment of the present application;

FIG. 14 is a schematic structural diagram of a chip packaging unit including two layers of traces;

FIG. 15 is a cross-sectional view along the direction of EE1 of FIG. 14;

FIG. 16 is a cross-sectional view along the direction of E2E3 of FIG. 14;

FIG. 17 is a schematic structural diagram of a chip packaging unit including two lead-wire units;

FIG. 18 is a schematic structural diagram of yet another chip packaging unit according to an embodiment of the present application;

FIG. 19 and FIG. 20 are schematic structural diagrams of two types of chip packaging component including two chips according to the embodiments of the present application;

FIG. 21-FIG. 24 are schematic structural diagrams of four types of arrangement of a plurality of first leads according to the embodiments of the present application;

FIG. 25 is a schematic structural diagram of a display device according to an embodiment of the present application; and

FIG. 26-FIG. 27 are schematic structural diagrams of two types of display panel and chip packaging component according to the embodiments of the present application.

FIG. 28 is a planar schematic structural diagram of a chip-on-film according to an embodiment of the present application;

FIG. 29 is a schematic structural diagram of a chip-on-film according to an embodiment of the present application;

FIG. 30a, FIG. 30b and FIG. 30c are partial schematic structural diagrams of chip bonding regions in a chip-on-film;

FIG. 31 is a partial schematic structural diagram of a chip bonding region in another chip-on-film;

FIG. 32 is a flow chart of a method for manufacturing a chip-on-film according to an embodiment of the present application;

FIG. 33 is a flow chart of a method for manufacturing a chip-on-film according to an embodiment of the present application;

FIG. 34 is a planar schematic structural diagram of a chip-on-film in the related art;

FIG. 35 is a planar schematic structural diagram of a display module according to an embodiment of the present application;

FIG. 36 is a planar schematic structural diagram of another display module according to an embodiment of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first”, “second” and “third” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the meaning of “plurality of” is “two or more”, and the meaning of “at least one” is “one or more”, unless explicitly and particularly defined otherwise.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

A traditional chip-on-film is implemented using a roll-to-roll process route, and the number of channels is often less than 2000. To achieve a higher number of channels, a double-sided copper process is required. This technology is costly and are not widely used, and the number of channels currently achievable by the double-sided copper process is within 4000, making it difficult to further increase the number of channels.

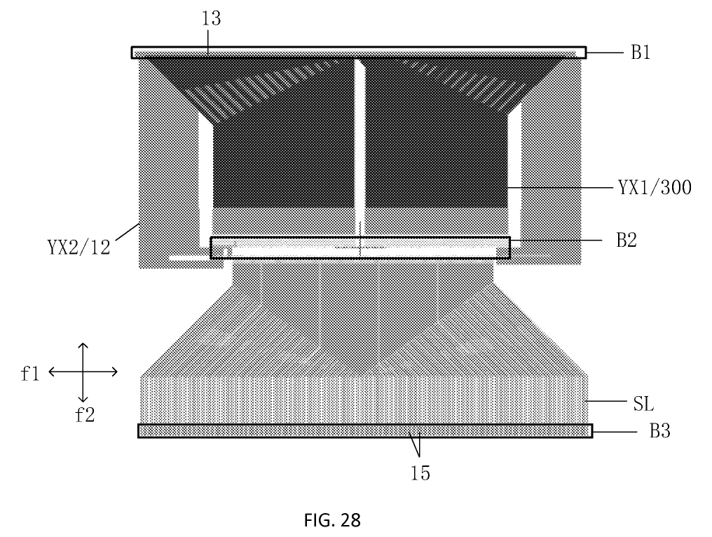

Referring to FIG. 28, which exemplarily illustrates a planar structure schematic diagram of a chip-on-film according to an embodiment of the present application. As shown in FIG. 28, the chip-on-film includes a chip bonding region B2 and a panel bonding region B1 spaced apart from each other. The chip bonding region B2 is used for bonding a chip 14, and the panel bonding region B1 is used for bonding a display panel 2.

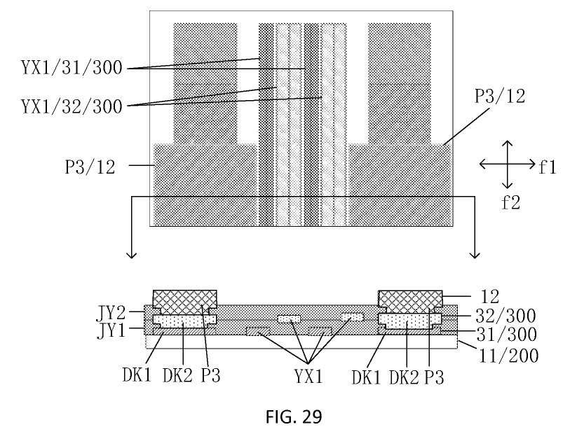

Referring to FIG. 29, which exemplarily illustrates schematic plan and cross-sectional structural diagrams of the chip bonding region B2 according to an embodiment of the present application. As shown in FIG. 29, the chip-on-film includes: a substrate 200; one or more wiring layers 300, the plurality of wiring layers 300 being stacked in a direction perpendicular to the substrate 200, each wiring layer 300 including a plurality of through leads YX1 spaced apart from each other; and a lead layer 12 disposed on a side of all of the wiring layers 300 facing away from the substrate 200, the lead layer 12 including a plurality of third leads P3 located in the chip bonding region B2, the plurality of third leads P3 being arranged in an array along a first direction f1 and a second direction f2, respectively, the first direction f1 and the second direction f2 intersecting each other. For example, the first direction f1 and the second direction f2 may be perpendicular to each other, and the third leads P3 may, for example, extend along the second direction f2.

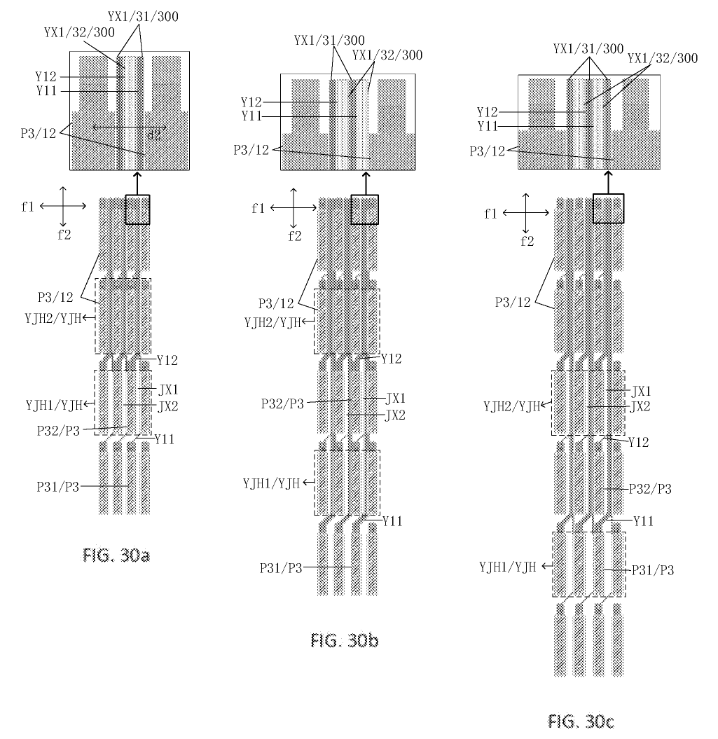

Referring to FIG. 30a, FIG. 30b and FIG. 30c, which exemplarily illustrate three planar structure schematic diagrams of the chip bonding region B2. As shown in FIG. 28, FIG. 30a, FIG. 30b and FIG. 30c, the third leads P3 are connected to the panel bonding region B1 via the through leads YX1, and the orthographic projections of the through leads YX1 on the substrate 200 overlap with lead gaps in the chip bonding region B2, each lead gap being a gap between two adjacent third leads P3 arranged along the first direction f1.

In the chip-on-film according to an embodiment of the present application, by disposing the third leads P3 and the through leads YX1 in different layers, respectively, the through leads YX1 may pass through the lead gaps of the third leads P3 without causing short circuits, and can also reduce gaps between the through leads YX1 and the third leads P3, thereby helping to increase wiring density and increase the number of channels of the chip-on-film. For example, the number of channels of the chip-on-film is greater than or equal to 4000, or even greater than or equal to 10000. Since the wiring density is increased, the technical solution of the present application can also improve the space utilization rate of the chip-on-film, and under the condition that the number of channels remains unchanged, can save the space occupied by leads YX, reduce the area of the chip-on-film, and save costs.

In addition, since the wiring layer 300 and the lead layer 12 are disposed on the same side of the substrate 200, there is no need to set holes in the substrate 200 to connect the wiring layer 300 and the lead layer 12, thereby simplifying the fabrication process and improving yield.

For any third lead P3, the through lead YX1 connected to the third lead P3 is a target lead. Exemplarily, as shown in FIG. 29, pads (such as a first pad DK1 and a second pad DK2 shown in FIG. 29) are disposed between the third lead P3 and the substrate 200, and the third lead P3 is connected to the target lead via via holes. The target lead is integrated with a pad disposed in the same layer, thereby achieving a connection between the third lead P3 and the target lead. In the orthographic projection on the substrate 200, the pad at least covers a geometric center of the third lead P3, and the provision of the pad can provide support to the third lead and improve the stability of the third lead.

Exemplarily, the number of wiring layers 300 is greater than or equal to 1.

Exemplarily, in the orthographic projection on the substrate 200, two adjacent through leads YX1 that overlap with a same lead gap may overlap with each other, which can further increase wiring density or reduce the area of the chip-on-film.

Exemplarily, as shown in FIG. 30a, FIG. 30b and FIG. 30c, in the orthographic projection on the substrate 200, two adjacent through leads YX1 that overlap with a same lead gap may also not overlap with each other, which can reduce coupling capacitance and avoid signal crosstalk.

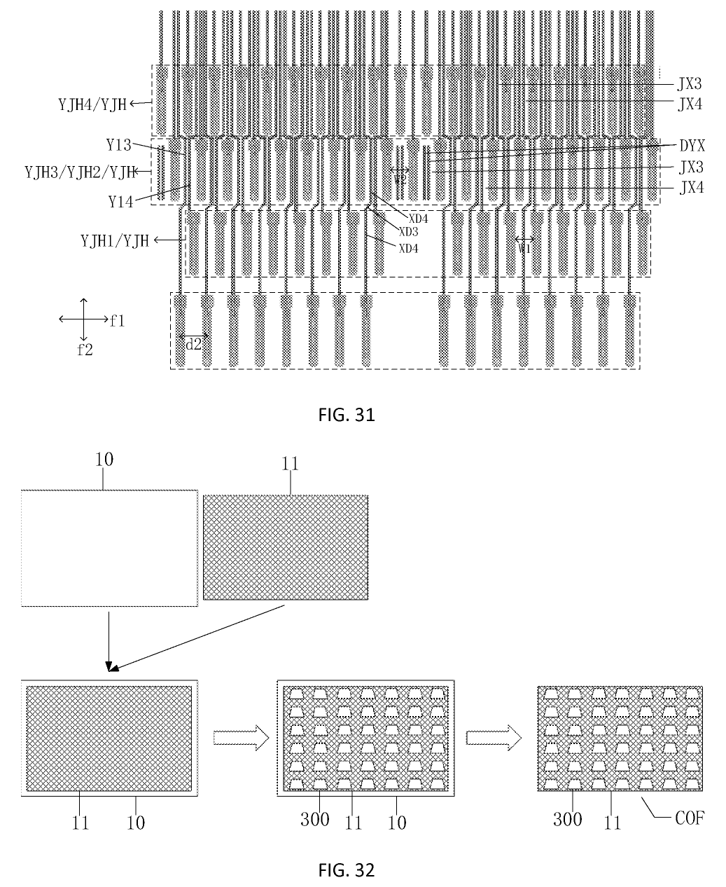

Referring to FIG. 32, the chip-on-film according to an embodiment of the present application may be manufactured using the following steps:

Step S10: first, attaching the flexible substrate 11 onto the rigid substrate 10 by means of an adhesive or a silane coupling agent, etc., to convert flexible processing into rigid processing, thereby enabling the use of exposure equipment with higher resolution capability and related materials, which facilitates the fabrication of ultra-high-density circuits. Wherein, the flexible substrate 11 is, for example, a PI film (polyimide), etc., and the rigid substrate 10 is, for example, glass, etc.

Step S20: forming the wiring layer 300 and the lead layer 12 on the side of the flexible substrate 11 facing away from the rigid substrate 10 by using a patterning process. After completion of step S20, the flexible substrate 11 can be separated from the rigid substrate 10 to obtain the chip-on-film COF (as shown in FIG. 32).

It should be noted that the chip-on-film may also be bonded to the display panel 2 with the rigid substrate 10 still attached, and then the flexible substrate 11 and the rigid substrate 10 are separated or selectively separated. Exemplarily, the substrate 200 may include the flexible substrate 11, or may include the flexible substrate 11 and the rigid substrate 10 attached to each other, and the wiring layer 300 and the lead layer 12 are disposed on the side of the flexible substrate 11 facing away from the rigid substrate 10.

Taking three wiring layers 300 as an example, step S20 will be described below. Step S20, for example, includes:

Step S11: depositing an adhesion layer and a seed layer sequentially over the entire surface on the side of the flexible substrate 11 facing away from the rigid substrate 10; wherein, the material of the adhesion layer may, for example, be titanium or molybdenum-nickel-titanium alloy target (MTD), and the seed layer may, for example, be thin copper.

Step S12: coating photoresist, expose and develop the photoresist, removing the photoresist in a first preset region;

Step S13: electroplating thick copper to form thick copper in the first preset region overlapping with the first wiring layer 31;

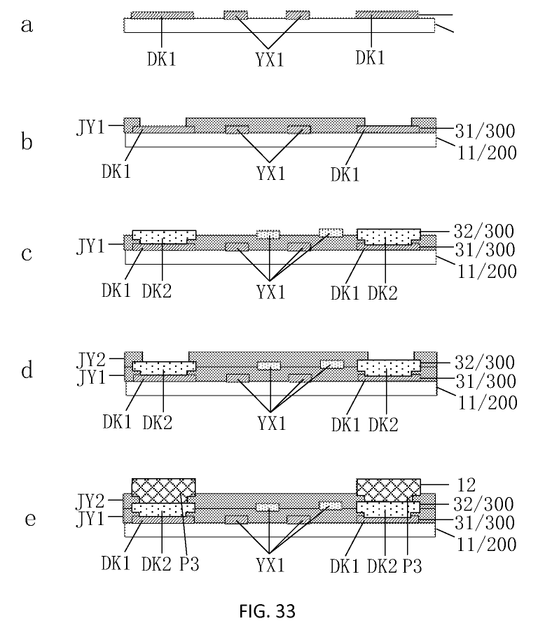

Step S14: removing the photoresist, and perform overall etching to etch away the top of the thick copper in the first preset region and the seed layer and the adhesion layer of other regions, thereby forming the first wiring layer 31, as shown in portion a of FIG. 33. The first wiring layer 31 includes a plurality of leads YX and a plurality of first pads DK1, the leads YX of the first wiring layer 31 being connected to the first pads DK1 in one-to-one correspondence, and the orthographic projections of the first pads DK1 and a central region of the third leads P3 on the substrate 200 overlapping with each other;

Step S15: coating an insulating material, form via holes by an exposure and development process, to form a first insulating layer JY1, as shown in portion b of FIG. 33; the first insulating layer JY1 can achieve both insulation between the first wiring layer 31 and a second wiring layer 32 and formation of interconnection channels; wherein, the insulating material is, for example, polyimide;

Step S16: depositing an adhesion layer and a seed layer sequentially over the entire surface on the side of the first insulating layer JY1 facing away from the rigid substrate 10;

Step S17: coating photoresist, exposing and developing the photoresist, removing the photoresist in a second preset region;

Step S18: electroplating thick copper to form thick copper in the second preset region overlapping with the second wiring layer 32;

Step S19: removing the photoresist, and performing overall etching to etch away the top of the thick copper in the second preset region and the seed layer and the adhesion layer of other regions, thereby forming the second wiring layer 32, as shown in portion c of FIG. 33. The second wiring layer 32 includes a plurality of leads YX and a plurality of second pads DK2, the leads YX of the second wiring layer 32 being connected to the second pads DK2 in one-to-one correspondence, and the orthographic projections of the second pads DK2 and the central region of the third leads P3 on the substrate 200 overlapping with each other;

Step S20: coating an insulating material, forming via holes by an exposure and development process, to form a second insulating layer JY2, as shown in portion d of FIG. 33; the second insulating layer JY2 can achieve both insulation between the second wiring layer 32 and the lead layer 12 and formation of interconnection channels;

Step S21: depositing an adhesion layer and a seed layer sequentially over the entire surface on the side of the second insulating layer JY2 facing away from the rigid substrate 10;

Step S22: coating photoresist, exposing and developing the photoresist, removing the photoresist in a third preset region;

Step S23: electroplating thick copper to form thick copper in the third preset region overlapping with the lead layer 12;

Step S24: removing the photoresist, and performing overall etching to etch away the top of the thick copper in the third preset region and the seed layer and the adhesion layer of other regions, thereby forming the lead layer 12, as shown in portion e of FIG. 33. The lead layer 12 includes a plurality of third leads P3 arranged in an array, the third leads P3 are connected to the leads YX in the second wiring layer 32 via the second pads DK2, and the third leads P3 are connected to the leads YX in the first wiring layer 31 via the second pads DK2 and the first pads DK1. Wherein, each lead YX of the lead layer 12 is connected to one third lead P3. The number of channels of the chip-on-film prepared by the above manufacturing method is increased by more than 50% compared with conventional processes.

By using the above manufacturing method, in principle, a plurality of wiring layers 300 can be processed on the flexible substrate 11, and patterns of different wiring layers 300 can overlap with each other due to the insulating layers disposed therebetween, which can greatly increase the number of channels. In addition, the rigid processing can enable fabrication of ultra-high-resolution circuits and via holes, thereby further increasing the number of channels.

In some embodiments, as shown in FIG. 30a, FIG. 30b and FIG. 30c or shown in FIG. 31, the plurality of third leads P3 are divided into a plurality of lead rows YJH, each lead row YJH including a plurality of third leads P3 arranged along the first direction f1, the plurality of lead rows YJH being arranged along the second direction f2.

In some embodiments, as shown in FIG. 30a, FIG. 30b and FIG. 30c or shown in FIG. 31, the plurality of lead rows YJH include a first lead row YJH1 and a second lead row YJH2, the second lead row YJH2 being located between the first lead row YJH1 and the panel bonding region B1, and in the orthographic projection on the substrate 200, the through leads YX1 connected to the third leads P3 in the first lead row YJH1 overlap at least with lead gaps in the second lead row YJH2.

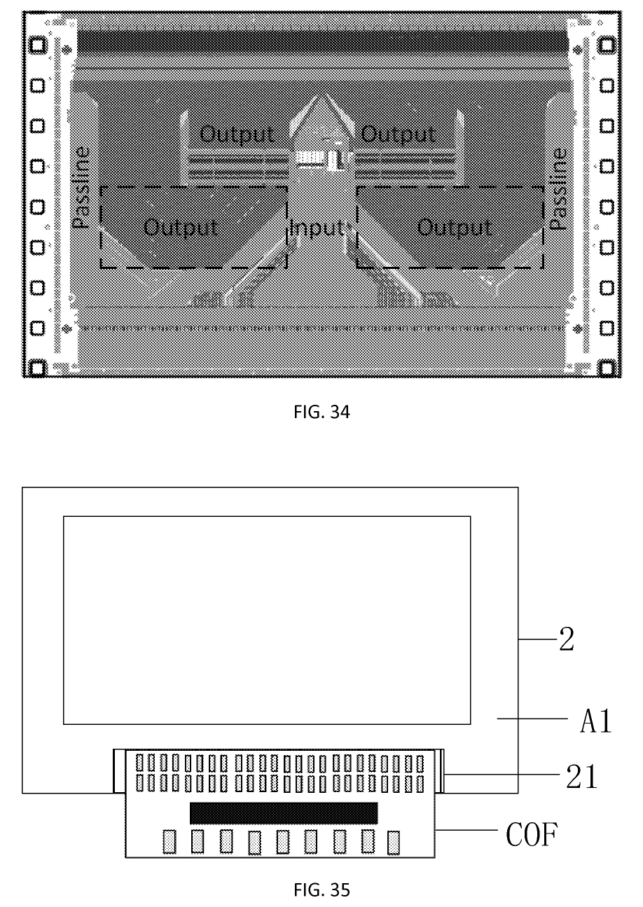

Since the through leads YX1 connected to the first lead row YJH1 may directly pass through the lead gaps in the second lead row YJH2 without needing to bypass to a peripheral region of the chip bonding region B2 (such as the dashed box region in the fan-out lead arrangement shown in FIG. 34), this straight-out lead arrangement can well utilize the advantages of the stacked wiring layers 300, i.e., high-density interconnect technology, and compared with the fan-out lead arrangement (as shown in FIG. 34), can further reduce the area of the chip-on-film and achieve lower product cost.

Wherein, the first lead row YJH1 and the second lead row YJH2 may be two adjacently arranged lead rows YJH, or other lead rows YJH may also be disposed between the first lead row YJH1 and the second lead row YJH2, which is not limited in the present application.

In some embodiments, as shown in FIG. 30a, FIG. 30b or FIG. 30c, the third leads P3 in two adjacent lead rows YJH are aligned along the first direction f1, which helps simplify design and process.

Exemplarily, as shown in FIG. 30a, FIG. 30b or FIG. 30c, the pitch d2 of the third leads in different lead rows is the same, the third lead pitch d2 being the center-to-center distance between two adjacent third leads P3 arranged along the first direction f1.

In some embodiments, as shown in FIG. 30a, FIG. 30b or FIG. 30c, the plurality of third leads P3 arranged along the second direction f2 include a first sub-lead P31 and a second sub-lead P32, the second sub-lead P32 being located between the first sub-lead P31 and the panel bonding region B1, the through lead YX1 connected to the first sub-lead P31 being a first through lead Y11, and the through lead YX1 connected to the second sub-lead P32 being a second through lead Y12; in the orthographic projection on the substrate 200, the lead gaps overlapping with the second through lead Y12 also overlap with the first through lead Y11.

Exemplarily, as shown in FIG. 30a, FIG. 30b or FIG. 30c, the plurality of third leads P3 arranged along the second direction f2 constitute a lead column, and for any lead column, the plurality of through leads YX1 connected to the lead column are located within a lead gap between the lead column and an adjacent lead column.

In some embodiments, as shown in FIG. 30a, FIG. 30b or FIG. 30c, a plurality of lead gaps in a same lead row YJH include a first lead gap JX1 and a second lead gap JX2, and in the orthographic projection on the substrate 200, a number of the through leads YX1 overlapping with the first lead gap JX1 is equal to a number of the through leads YX1 overlapping with the second lead gap JX2. This helps reduce differences in loads of different through leads, helps improve display uniformity, and also helps improve process uniformity.

For example, as shown in FIG. 30a, in the orthographic projection on the substrate 200, the number of the through leads YX1 overlapping with the lead gaps in the first lead row YJH1 is all 1, and the number of the through leads YX1 overlapping with the lead gaps in the second lead row YJH2 is all 2.

In some embodiments, as shown in FIG. 31, the third leads P3 in two adjacent lead rows YJH are staggered along the first direction f1. For lead gaps with a smaller number of through leads YX1 passing through, the width of the lead gaps can be reduced, thereby further increasing wiring density and increasing the number of channels or saving space within a limited area.

Exemplarily, the pitch d2 of the third leads in different lead rows YJH may be the same (as shown in FIG. 31) or different, the third lead pitch d2 being the center-to-center distance between two adjacent third leads P3 arranged along the first direction f1. In the case where the pitch d2 of the third leads in different lead rows YJH is different, the number of channels can be increased or space can be saved within a limited area.

Exemplarily, in the case where the pitch d2 of the third leads in different lead rows YJH is the same, a staggering distance of two adjacent lead rows YJH is less than or equal to one half of a distance between two adjacent third leads in a same lead row YJH.

In some embodiments, as shown in FIG. 31, the plurality of lead rows YJH include a third lead row YJH3 and a fourth lead row YJH4, the fourth lead row YJH4 being located between the third lead row YJH3 and the panel bonding region B1; the plurality of through leads YX1 include a third through lead YX13 and a fourth through lead YX14, and in the orthographic projection on the substrate 200, the third through lead YX13 and the fourth through lead YX14 overlap with a same lead gap in the third lead row YJH3, and the third through lead YX13 and the fourth through lead YX14 respectively overlap with different lead gaps in the fourth lead row YJH4. Such a wiring arrangement helps increase the number of channels or save space within a limited area, and also helps match the lead design on the chip, thereby reducing costs.

Exemplarily, as shown in FIG. 31, the lead gap overlapping with the third through lead YX13 and the lead gap overlapping with the fourth through lead YX14 in the fourth lead row YJH4 are two adjacent lead gaps.

In some embodiments, as shown in FIG. 31, a plurality of lead gaps in a same lead row YJH include a third lead gap JX3 and a fourth lead gap JX4, and in the orthographic projection on the substrate 200, a number of the through leads YX1 overlapping with the third lead gap JX3 is less than or equal to a number of the through leads YX1 overlapping with the fourth lead gap JX4.

For example, in FIG. 31, for the third lead gap and the fourth lead gap marked by dashed boxes, in the orthographic projection on the substrate 200, the number of the through leads YX1 overlapping with the third lead gap is less than the number of the through leads YX1 overlapping with the fourth lead gap; for the third lead gap and the fourth lead gap marked by solid boxes, in the orthographic projection on the substrate 200, the number of the through leads YX1 overlapping with the third lead gap is equal to the number of the through leads YX1 overlapping with the fourth lead gap.

In some embodiments, as shown in FIG. 31, in the orthographic projection on the substrate 200, the number of the through leads YX1 overlapping with the third lead gap (shown by the dashed box in FIG. 31) is less than the number of the through leads YX1 overlapping with the fourth lead gap (shown by the dashed box in FIG. 31); and the wiring layer further includes a dummy lead, the dummy lead being disposed spaced apart from the through leads YX1 and the third leads P3, respectively, and not connected to each other. In the orthographic projection on the substrate 200, the dummy lead overlaps with the third lead gap, and a total number of the dummy lead(s) and the through leads YX1 overlapping with the third lead gap is equal to the number of the through leads YX1 overlapping with the fourth lead gap. This can improve the consistency of the etching environment for different third leads and improve process precision.

In some embodiments, as shown in FIG. 29, the chip-on-film includes a plurality of wiring layers 300, and in the orthographic projection on the substrate 200, two adjacent through leads YX1 that overlap with a same lead gap are disposed in different layers.

For example, in FIG. 29, there are four through leads YX1 overlapping the same lead gap, which are sequentially located in the first lead layer 31, the second lead layer 32, the first lead layer 31, and the second lead layer 32.

Exemplarily, in a case where the lead layer 300 further includes dummy leads DYX, in an orthographic projection on the base substrate 200, a through lead YX1 and a dummy lead DYX that overlap the same lead gap and are adjacent to each other are arranged in different layers, or two through leads YX1 that overlap the same lead gap and are adjacent to each other are arranged in different layers.

In some embodiments, as shown in FIG. 31, in the orthographic projection on the substrate 200, the lead gaps in both the first lead row YJH1 and the second lead row YJH2 overlap with the through leads YX1, and a number of the through leads YX1 overlapping with the lead gaps in the first lead row YJH1 is less than a number of the through leads YX1 overlapping with the lead gaps in the second lead row YJH2.

For example, in FIG. 31, the number of the through leads YX1 overlapping with one lead gap in the first lead row YJH1 is 1, and the number of the through leads YX1 overlapping with one lead gap in the second lead row YJH2 is 3.

In some embodiments, as shown in FIG. 31, along the first direction f1, a width W2 of the lead gaps in the second lead row YJH2 is greater than or equal to a width W1 of the lead gaps in the first lead row YJH1.

Exemplarily, in the case where the number of the through leads YX1 overlapping with the lead gaps in the second lead row YJH2 is greater than the number of the through leads YX1 overlapping with the lead gaps in the first lead row YJH1, the width W2 of the lead gaps in the second lead row YJH2 is greater than the width W1 of the lead gaps in the first lead row YJH1.Since a larger number of through leads YX1 pass through a single lead gap in the second lead row YJH2, providing a wider lead gap in the second lead row YJH2 can reduce the risk of short circuit among the through leads YX1 and also reduce coupling capacitance. In addition, since a smaller number of through leads YX1 pass through a single lead gap in the first lead row YJH1, providing a narrower lead gap in the first lead row YJH1 can improve space utilization and save routing space.

In some embodiments, as shown in FIG. 28, the lead layer 12 further includes a bypass lead YX2, the bypass lead YX2 being disposed spaced apart from the third leads P3, and an orthographic projection of the bypass lead YX2 on the substrate 200 does not overlap with the lead gaps.

In some embodiments, as shown in FIG. 31, the through lead YX1 includes third line segments XD3 and fourth line segments XD4 alternately connected, the third line segments XD3 extending along the second direction f2, and an extension direction of the fourth line segments XD4 intersecting both the first direction f1 and the second direction f2, respectively.

In some embodiments, as shown in FIG. 31, in a case where two ends of the third line segment XD3 are each connected to one fourth line segment XD4, the two fourth line segments XD4 connected to the same third line segment XD3 have different extension directions. Such a wiring arrangement helps increase the number of channels or save space within a limited area.

In some embodiments, as shown in FIG. 29, a thickness of the lead layer 12 is greater than a thickness of the lead layer 300. For example, the thickness of the lead layer 12 ranges from 6 μm to 8 μm, and the thickness of the lead layer 300 ranges from 2 μm to 4 μm.

In some implementations, as shown in FIG. 28, the lead layer 12 further includes a plurality of first leads 13 located in the panel bonding region B1, and the first leads 13 are connected to the third leads P3 through the through leads YX1.

In some embodiments, as shown in FIG. 28, the chip-on-film further includes a driving board bonding region B3, the driving board bonding region B3 and the panel bonding region B1 being disposed opposite to each other along the second direction f2 on two sides of the chip bonding region B2; and the lead layer 12 further includes a plurality of second leads 15 located in the driving board bonding region B3, an input lead located in the chip bonding region B2, and an input signal line (not shown in FIG. 28), the input signal line being connected between the second leads 15 and the input lead.

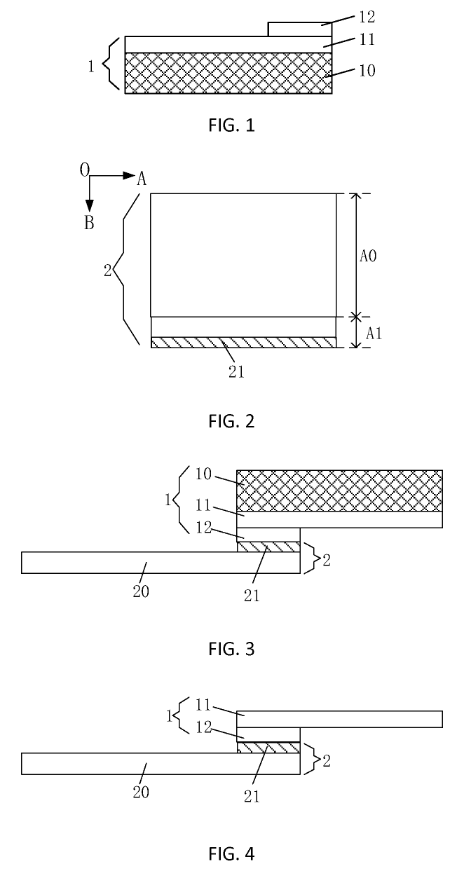

In some embodiments, as shown in FIG. 1, the panel bonding region B1 includes a plurality of first leads 13, and the substrate 200 includes: a flexible substrate 11, and a rigid substrate 10 disposed on a side of the flexible substrate 11 away from the wiring layer 300, and the orthographic projection of the plurality of first leads 13 on the flexible substrate 11 is located within the orthographic projection of the rigid substrate 10 on the flexible substrate 11. This can alleviate problems such as thermal stress and high-temperature bubbles generated during bonding of the chip-on-film and the display panel 2 due to high temperature and high pressure.

The present application provides a display module. As shown in FIG. 35, the display module includes: a display panel 2, the display panel 2 including a non-display area A1, the non-display area A1 including a bonding portion 21; and the chip-on-film COF as provided by any embodiment, the panel bonding region B1 of the chip-on-film COF being bonded to the bonding portion 21.

The display module according to an embodiment of the present application can be applied in the field of 3D display technology, and can provide more data channels for 3D display, thereby enabling the display module to have ultra-high resolution.

It should be noted that the present application does not particularly limit the type of the display panel 2, and the type thereof may be a TN (Twisted Nematic) type, a VA (Vertical Alignment) type, an IPS (In-Plane Switching) type, or an ADS (Advanced Super Dimension Switch) type, etc., liquid crystal display panel 2, and may also be an OLED (Organic Light-Emitting Diode) display panel 2.

In some embodiments, as shown in FIG. 28, the chip-on-film COF further includes a driving board bonding region B3, the driving board bonding region B3 and the panel bonding region B1 being disposed opposite to each other along the second direction f2 on two sides of the chip bonding region B2.

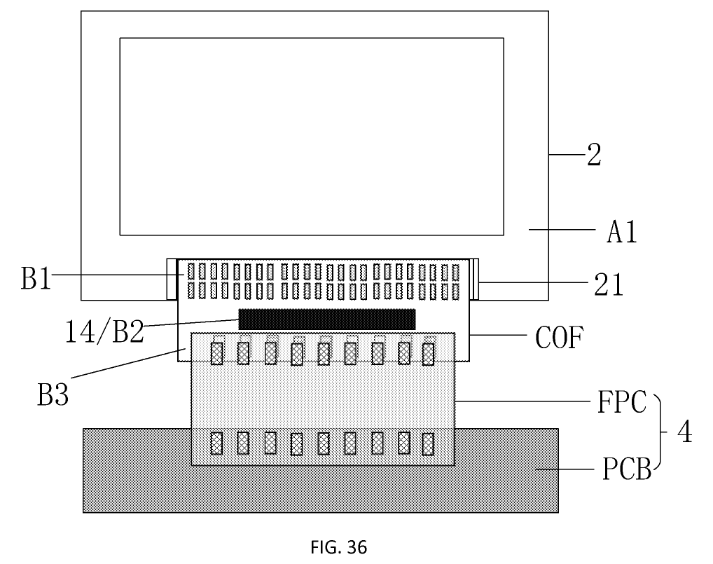

In some embodiments, as shown in FIG. 36, the display module further includes at least one of: a chip 14, bonded at least to the third leads P3 in the chip bonding region B2; and a driving board 4, bonded to the driving board bonding region B3.

In some embodiments, as shown in FIG. 36, the driving board 4 includes: a flexible circuit board FPC and a rigid circuit board PCB, the flexible circuit board FPC being connected between the driving board bonding region B3 and the rigid circuit board PCB. Since the number of the second leads 15 in the driving board bonding region B3 is small, while the number of the first leads 13 in the panel bonding region B1 is large, by connecting the high-density-lead chip-on-film COF to the flexible circuit board FPC, the present embodiment can reduce the area of the high-density interconnect chip-on-film COF under the premise of satisfying requirements on the length of the structural member, thereby reducing costs.

The present disclosure provides a display device, including the chip-on-film film provided in any of the implementations, or including the display module provided in any of the implementations.

The display device provided in the present disclosure can be applied in the field of 3D display technology, and can provide more data channel numbers for 3D display, so that the display device has an ultra-high resolution.

The display device provided in the present disclosure can be any product or component having a display function, such as a game console, a mobile phone, a tablet computer, a television, a monitor, a laptop computer, a digital photo frame, a vehicle-mounted display device, a smart watch, a fitness wristband, a personal digital assistant, and the like.

A method for manufacturing a display device is provided by an embodiment of the present application, wherein the method includes:

S01: forming a chip packaging component, wherein the chip packaging component includes at least one chip packaging unit 1 shown in FIG. 1; and the chip packaging unit 1 includes at least a flexible substrate 11, a rigid substrate 10 disposed at one side of the flexible substrate 11, and a lead layer 12 disposed at the side of the flexible substrate 11 away from the rigid substrate 10, the lead layer includes at least a plurality of first leads (not shown in FIG. 1), and the orthographic projections of the plurality of first leads on the flexible substrate are located within the orthographic projection of the rigid substrate on the flexible substrate.

The material of the flexible substrate is not limited. As an example, the material of the flexible substrate may include a flexible material such as polyimide (PI). The material of the rigid substrate is not limited. As an example, the material of the rigid substrate may include a rigid material such as glass.

The specific method for forming the chip packaging component may be determined according to the specific structure. As an example, the rigid substrate, the flexible substrate and the lead layer may be formed sequentially.

It should be noted that the rigid substrate of the chip packaging unit may face the whole face of the flexible substrate, as shown in FIG. 1. Alternatively, it may also be disposed merely within the region corresponding to the first leads. Alternatively, it may also be disposed within the region corresponding to the first leads and other bonding regions (for example, a chip bonding region and/or a driving-board bonding region).

S02: forming a display panel shown in FIG. 2, wherein the display panel 2 includes a non-active area A1, and the non-active area A1 includes a rigid substrate and a bonding part 21 disposed on the rigid substrate.

The type of the display panel is not limited herein. It may be liquid-crystal display panels such as the TN (Twisted Nematic) type, the VA (Vertical Alignment) type, the IPS (In-Plane Switching) type and the ADS (Advanced Super Dimension Switch) type, and may also be an OLED (Organic Light Emitting Diode) display panel.

The material of the rigid substrate is not limited. As an example, the material of the rigid substrate may include a rigid material such as glass. The material of the rigid substrate may be the same as the material of the rigid substrate of the chip packaging unit, at this moment the coefficients of thermal expansion of the materials of the material of the rigid substrate and the material of the rigid substrate of the chip packaging unit are equal.

The display panel may further include an active area (AA), and the active area is connected to the non-active area. The active area refers to the region used to implement the displaying. The non-active area is generally used to dispose the driving circuits and so on.

S03: bonding-connecting the first leads of the chip packaging component and the bonding part of the display panel, to obtain the structure shown in FIG. 3.

In the related art, the chip packaging component includes a PI flexible matrix, the display panel includes a glass matrix, and the coefficients of thermal expansion of PI and glass are unequal. In a bonding process, it is required to employ temperature compensation; in other words, the upper base board and the lower base board are heated at different temperatures, thereby alignment of the upper base board and the lower base board is realized. Although the compensation can be partially realized, in the process of practical operation, there are a low position-aligning precision, a high loss in yield and a low bonding precision. In view of that, in the chip packaging component according to the present application, the orthographic projections of the plurality of first leads on the flexible substrate are located within the orthographic projection of the rigid substrate on the flexible substrate. At a same time, the bonding part of the display panel is disposed on the rigid substrate, and the coefficients of thermal expansion of the rigid substrate and the rigid substrate are equal or close. In the bonding process of the step S03, the compensation amount introduced by thermal expansion can be reduced to the utmost extent, thereby a high-precision bonding is realized.

Optionally, in order to save the room to the largest extent, to reduce the product size and facilitate the bending at a same time, after the step S03 of bonding-connecting the first leads of the chip packaging component and the bonding part of the display panel, the method further includes:

S04: removing a whole of the rigid substrate of the chip packaging unit, to obtain the structure shown in FIG. 4.

As an example, it may be stripped by laser stripping (LLO), thermal dissociation, mechanical dissociation and so on.

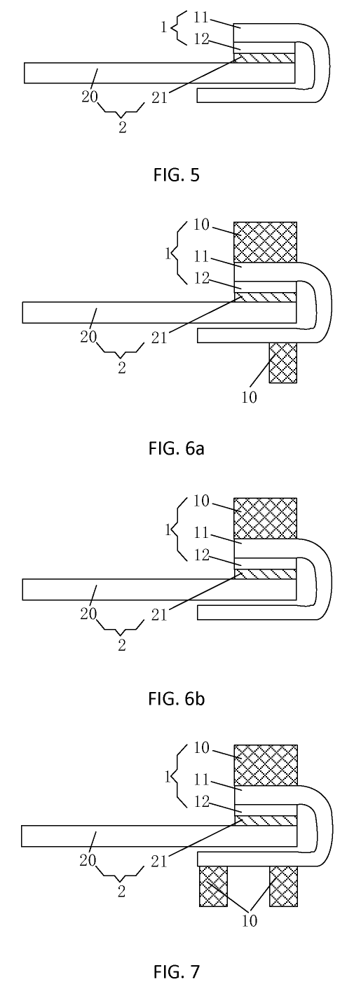

It should be noted that, after the step S03, the rigid substrate may also be maintained, or after being thinned by grinding and so on, the rigid substrate is subsequently taken into the terminal, which may be selected specifically according to practical demands. In order to further reduce the border frame, after the step S04, the chip packaging component is bent, to form the three structures shown in FIG. 5-FIG. 7. In FIG. 5, the whole of the rigid substrate of the chip packaging unit included by the terminal product is not maintained. In FIG. 6a, the rigid substrate of the chip packaging unit included by the terminal product within the region corresponding to the first leads and within the chip bonding region is maintained. In FIG. 6b, the rigid substrate of the chip packaging unit included by the terminal product within the region corresponding to the first leads is maintained. In FIG. 7, the rigid substrate of the chip packaging unit included by the terminal product within the region corresponding to the first leads, within the chip bonding region and within the driving-board bonding region is maintained.

Optionally, the coefficient of thermal expansion of the rigid substrate and the coefficient of thermal expansion of the rigid substrate are equal. As an example, both of the materials of the rigid substrate and the rigid substrate may include glass. Certainly, the coefficients of thermal expansion of the rigid substrate and the rigid substrate may also be close. As an example, the material of the rigid substrate may include glass, and the material of the rigid substrate may include PET (Polyethylene Terephthalate).

A display device is further provided by an embodiment of the present application, wherein the display device is formed by using the manufacturing method of the steps S01-S03 stated above, and the display device includes the chip packaging component and the display panel. The chip packaging component includes at least one chip packaging unit. Referring to FIG. 6 and FIG. 7, the chip packaging unit includes at least a flexible substrate 11, a rigid substrate 10 disposed at one side of the flexible substrate 11, and a lead layer 12 disposed at the side of the flexible substrate 11 away from the rigid substrate, the lead layer includes at least a plurality of first leads, and the orthographic projections of the plurality of first leads on the flexible substrate are located within the orthographic projection of the rigid substrate on the flexible substrate. The display panel includes a non-active area, and the non-active area includes a rigid substrate 20 and a bonding part 21 disposed on the rigid substrate 20. The first leads of the chip packaging component and the bonding part of the display panel are bonding-connected.

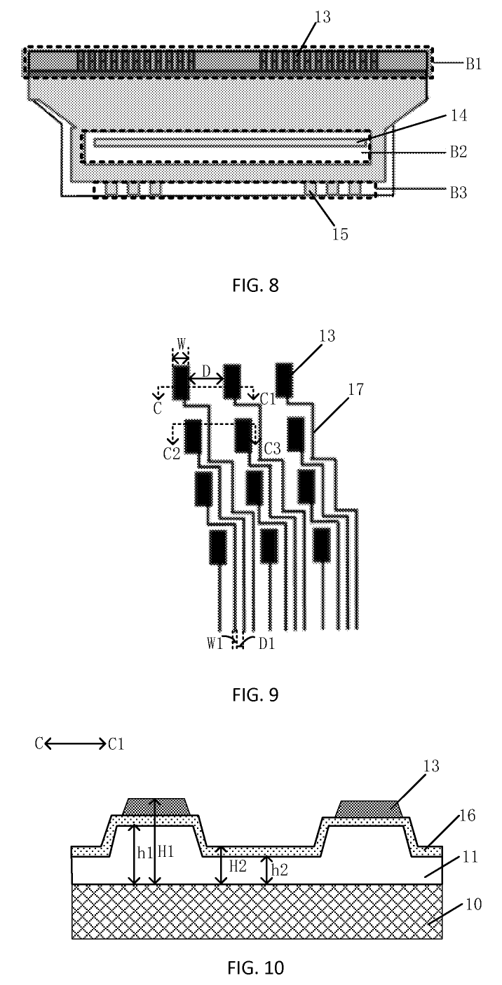

It should be noted that the chip packaging unit may include, as shown in FIG. 8, a panel bonding region B1, the chip bonding region B2, the driving-board bonding region B3 and a non-bonding region (the other region not encircled by a dotted line in FIG. 8). The panel bonding region is used to bond the display panel. The chip bonding region is used to bond the chip. The driving-board bonding region is used to bond the driving board. The first leads 13 may be disposed within the panel bonding region B1. In the chip packaging unit of the display device stated above, the rigid substrate may be disposed merely within the panel bonding region, or, in order to ensure the warping degree, the rigid substrate may be disposed within the panel bonding region and the driving-board bonding region, or the rigid substrate may be disposed within the panel bonding region, the chip bonding region and the driving-board bonding region, or the rigid substrate may be disposed at the whole region of the chip packaging unit, which is not limited herein.

Alternatively, the display device according to the embodiments of the present application may also be formed by using the manufacturing method of the steps S01-S04 stated above, and the display device includes the chip packaging component and the display panel. The chip packaging component includes at least one chip packaging unit. Referring to FIG. 4 and FIG. 5, the chip packaging unit includes a flexible substrate 11, and a lead layer 12 disposed at one side of the flexible substrate 11, and the lead layer includes at least a plurality of first leads. The display panel includes a non-active area, and the non-active area includes a rigid substrate 20 and a bonding part 21 disposed on the rigid substrate 20. The first leads of the chip packaging component and the bonding part of the display panel are bonding-connected.

The thickness of the flexible substrate is not limited. As an example, the range of the thickness may be 10-40 micrometers. It may be of a single-layer or multilayer structure, which is not limited herein.

In the above two types of display device, in the process of bonding the first leads of the chip packaging component and the bonding part of the display panel, the orthographic projections of the plurality of first leads on the flexible substrate are located within the orthographic projection of the rigid substrate on the flexible substrate. At the same time, the bonding part of the display panel is disposed on the rigid substrate, and the coefficients of thermal expansion of the rigid substrate and the rigid substrate are equal or close. Therefore, in the bonding process, the compensation amount introduced by thermal expansion can be reduced to the utmost extent, to reduce the bonding deviation and the bonding spacing, thereby a high-precision bonding is realized. The display devices can greatly increase the bonding precision of the chip packaging unit and the display panel, thereby the quantity of the output channels of the chip packaging unit is greatly increased, thus the requirements on high-resolution display products (for example, 3D-display products) are satisfied.

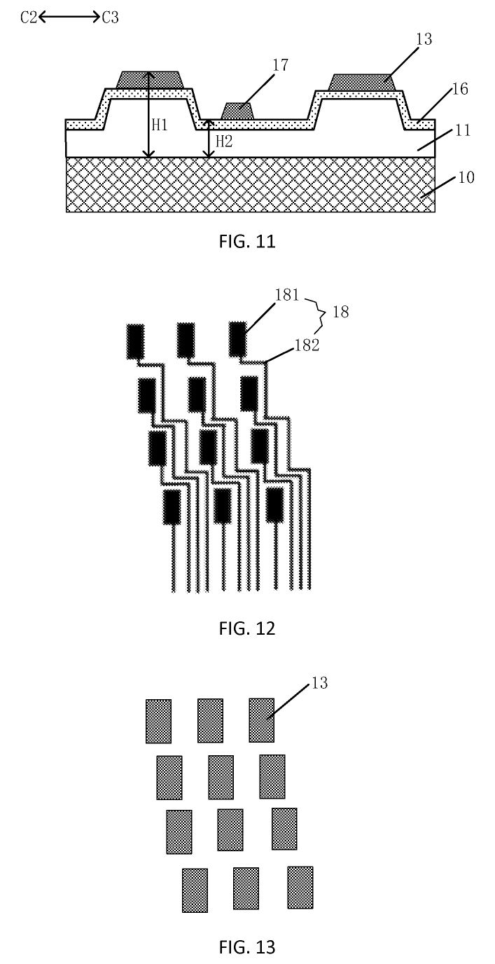

The first leads and the bonding part may be bonded by using an anisotropic electrically conductive adhesive (ACF, anisotropic Conductive Films). In order to provide a sufficient adhesive-overflowing room, to ensure the quality of the bonding, in one or more embodiments, referring to FIG. 10 and FIG. 11, the distance H1 from each of the first leads 13 to the flexible substrate 11 in the direction perpendicular to the flexible substrate 11 is greater than the distance H2 from a neighboring part of the first lead to the flexible substrate 11 in the direction perpendicular to the flexible substrate 11.

Optionally, in order to ensure a sufficient adhesive-overflowing room and reduce the product size at the same time, the range of the difference between the distance from each of the first leads to the flexible substrate in the direction perpendicular to the flexible substrate and the distance from the neighboring part of each of the first leads to the flexible substrate in the direction perpendicular to the flexible substrate is 2-8 micrometers. As an example, the difference may be 2 micrometers, 4 micrometers, 6 micrometers, 8 micrometers and so on.

The chip packaging unit may employ the single-layer-race structure shown in FIG. 10 and FIG. 11, or employ the multilayer-trace structure shown in FIG. 15 and FIG. 16, which is not limited herein.

A chip packaging unit including a plurality of layers of the traces will be provided below.

Optionally, the chip packaging unit further includes one or more lead-wire units. Referring to FIG. 15 and FIG. 16, the lead-wire units 3 are disposed between the lead layer and the flexible substrate 11. In an entirety formed by all of the lead-wire units, the distance H4 from the part not covered by the first leads to the flexible substrate in the direction perpendicular to the flexible substrate is less than the distance H3 from the part covered by the first leads to the flexible substrate in the direction perpendicular to the flexible substrate. The flexible substrate has a uniform thickness H in the direction perpendicular to the flexible substrate.

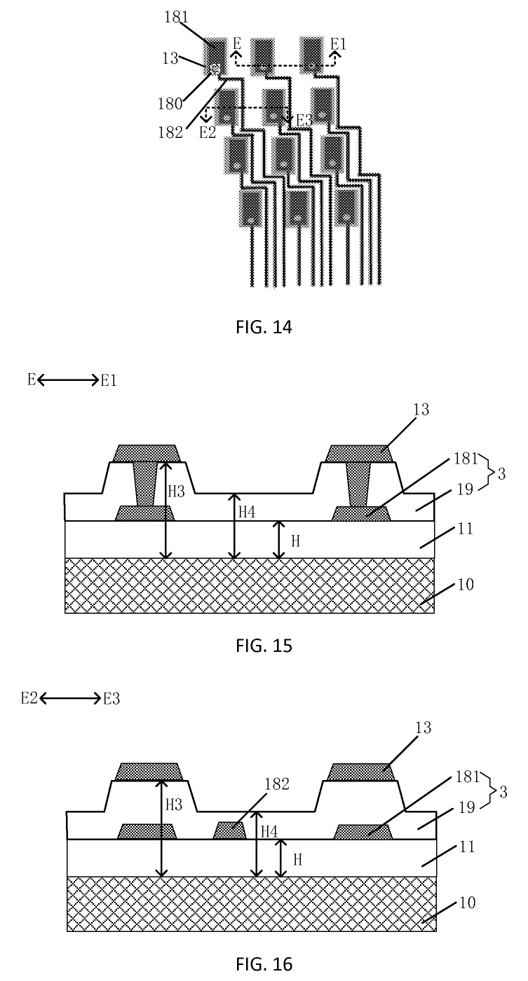

Referring to FIGS. 12 and 14-16, each of the lead-wire units 3 includes a first lead-wire layer 18 and a first organic layer 19, and the first organic layer 19 covers the first lead-wire layer 18. The first lead-wire layer 18 includes at least a plurality of first traces 182 and/or a plurality of first trace leads 181. The first traces 182 and/or the first trace leads 181 are electrically connected to the corresponding first leads 13. As an example, the first trace leads 181 may be electrically connected to the corresponding first leads 13 through the switching holes 180 shown in FIG. 14.

That the first lead-wire layer includes at least a plurality of first traces and/or a plurality of first trace leads includes three cases. In the first case, the first lead-wire layer includes at least a plurality of first traces, at this moment, the first traces are electrically connected to the corresponding first leads, and the first traces and the first leads may overlap or not overlap in the direction perpendicular to the flexible substrate. In the second case, the first lead-wire layer includes at least a plurality of first trace leads, at this moment, the first trace leads are electrically connected to the corresponding first leads, and at this moment, the first trace leads and the first leads may overlap or not overlap in the direction perpendicular to the flexible substrate. In the third case, the first lead-wire layer includes at least a plurality of first traces 182 and a plurality of first trace leads 181, as shown in FIG. 12, at this moment the first traces and the first trace leads are electrically connected to the corresponding first leads, the first traces and the first trace leads may be arranged in the same layer, and the first trace leads and the first traces may individually overlap or not overlap with the first leads in the direction perpendicular to the flexible substrate; in order to reduce the generation of parasitic capacitance, referring to FIG. 14, the first traces 182 and the first leads 13 do not overlap in the direction perpendicular to the flexible substrate; and in order to save the room and reduce the spacing, referring to FIG. 14, the first trace leads 181 and the first leads 13 overlap in the direction perpendicular to the flexible substrate, and, further, the orthographic projections of the first trace leads on the flexible substrate are located within the orthographic projections of the first leads on the flexible substrate. The arrangement in the same layer used herein refers to that they are fabricated by using a one-step patterning process. The one-step patterning process refers to a process that the required layer structure is formed by a single exposure. The one-step patterning process includes the processes of masking, exposure, development, etching, stripping and so on.

The specific layer structures of the first traces and the first trace leads are not limited herein. As an example, each of the first traces and the first trace leads may include one conductive layer, for example, a copper conductive layer. Alternatively, each of them may also include a plurality of conductive layers, for example, a three-layer tandem structure of a titanium conductive layer, an aluminum conductive layer and a titanium conductive layer, or a three-layer tandem structure of a molybdenum conductive layer, an aluminum conductive layer and a molybdenum conductive layer.

Herein the specific layer structures of the first traces and the first trace leads and the specific layer structure of the first leads may be the same, or may also be different, which is not limited herein.

The first organic layer may be of a single-layer structure or a multilayer structure, which is not limited herein. The thickness of the first organic layer may be 5-10 micrometers. If the first organic layer is of a multilayer structure, the materials of the organic layers may be the same or different.

In such a structure, by disposing the lead layer and the first lead-wire layer, the functions of the first leads and the first traces can be realized respectively, thereby leads of a higher quantity are further provided is realized, the quantity of the output channels of the chip packaging component is further increased.

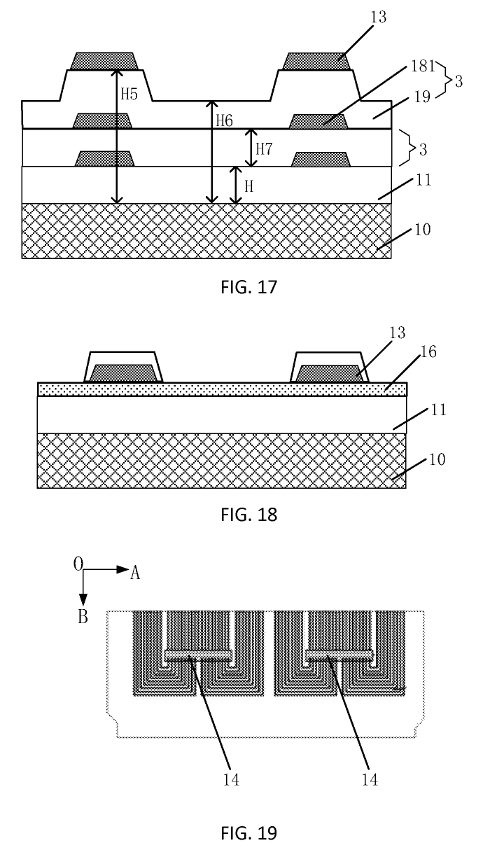

Optionally, among all of the lead-wire units, referring to FIG. 17, in the first organic layer 19 of the lead-wire unit 3 contacted with the first lead 13, the distance H6 from the part not covered by the first leads to the flexible substrate in the direction perpendicular to the flexible substrate is less than the distance H5 from the part covered by the first leads to the flexible substrate in the direction perpendicular to the flexible substrate. The other of the lead-wire units has a uniform thickness H7 in the direction perpendicular to the flexible substrate. Such a structure is simple and easy to implement, and it is merely required to pattern the first organic layer of the lead-wire unit contacted with the first lead, to ensure a sufficient adhesive-overflowing room. FIG. 17 is illustrated by taking the case as an example in which two lead-wire units are included.

In one or more embodiments, because the flexible substrate is fabricated by using an organic material, and is easily eroded by water and oxygen, in order to prevent water-oxygen erosion, the chip packaging unit further includes a water-oxygen insulating layer 16 shown in FIG. 10, the water-oxygen insulating layer 16 covers the flexible substrate 11, and the lead layer is disposed at the side of the water-oxygen insulating layer away from the flexible substrate. Referring to FIG. 10, in the flexible substrate 11, the thickness h2 of the part not covered by the first leads 13 is less than the thickness h1 of the part covered by the first leads. The thickness of the water-oxygen insulating layer is not limited. As an example, the range of the thickness is 100-500 nanometers. The material of the water-oxygen insulating layer may include silicon dioxide or silicon nitride.

In one or more embodiments, each of the first leads includes at least one conductive layer, and the material of the conductive layer includes a metal or a metal alloy. As an example, the material of the conductive layer may include a metal such as Mo, Al, Ti and Cu or an alloy. Taking copper as an example, the first leads may be formed by etching a thick copper plate or electroplating thick copper, and the thickness of the copper is approximately 8 micrometers. Because the isotropy of wet etching, a very low dimensional deviation (CD Bias) is difficult to obtain, and therefore the spacing between the formed leads is greater than 16 micrometers.

Optionally, if the first lead includes one conductive layer, if the first lead is fabricated by using an easily oxidized material such as copper, in order to prevent copper oxidation, the first lead further includes an anti-oxidation layer 13, and the anti-oxidation layer covers the conductive layer. The anti-oxidation layer may employ process of chemical plating of Sn and Au and so on, and the range of the thickness is 0.5μm-2μm. Alternatively, the surface of the first lead may also be covered by ITO (Indium Tin Oxide), to prevent oxidation. In addition, the anti-oxidation layer further facilitates to increase the height of the region where the first lead is located, to ensure a sufficient adhesive-overflowing room in the subsequent bonding with the panel.

In order to protect the non-bonding region, optionally, a solder-resist layer (for example, green oil) may be disposed within the non-bonding region of the chip packaging unit, and the range of the thickness is 5-20 micrometers.

Optionally, if the first lead includes a plurality of conductive layers, the first lead includes a first conductive layer, a second conductive layer and a third conductive layer that are arranged in layer configuration on the flexible substrate; and each of the thickness of the first conductive layer in the direction perpendicular to the flexible substrate and the thickness of the third conductive layer in the direction perpendicular to the flexible substrate is less than the thickness of the second conductive layer in the direction perpendicular to the flexible substrate.

The material of the first conductive layer and the material of the third conductive layer may be the same or different. The second conductive layer may employ a metal material such as aluminum, and the first conductive layer and the third conductive layer may employ metal materials such as molybdenum and titanium, in this way, finer wiring can be formed by the process of photoetching, electroplating and so on, and the trace spacing (pitch) can be reduced to below 16 micrometers, or even reduced to approximately several micrometers (for example, 3.6 micrometers or 5 micrometers). By contrast, if the conductive layers are fabricated by using copper, the trace spacing (pitch) is at least 16-18 micrometers. The multilayer tandem structure, as compared with the single-copper-layer structure, can reduce the wiring room to a great extent, so that the chip packaging unit can provide more output leads, to satisfy the requirements of high-resolution display products and 3D-display products. It should be noted that, as shown in FIG. 9, the trace spacing refers to the sum of the line width W1 of the trace (the trace 17 shown in FIG. 9) and the spacing D1 between the neighboring traces, and the lead spacing refers to the sum of the width W of the lead (the first lead 13 shown in FIG. 9) and the spacing D between the neighboring leads.

In order to simplify the process, the material of the first conductive layer and the material of the third conductive layer are the same, and the material of the first conductive layer and the material of the second conductive layer are different. As an example, the material of the second conductive layer may include aluminum and so on, and the material of the first conductive layer and the third conductive layer may include molybdenum, titanium and so on.

In some embodiments, the chip packaging unit further includes one or more lead-wire units, and the lead-wire units are disposed between the lead layer and the flexible substrate. Each of the lead-wire units includes a first lead-wire layer and a first organic layer, and the first organic layer covers the first lead-wire layer.

The first lead-wire layer includes a plurality of first traces, and the layer structure included by the first traces and the layer structure included by the first leads are the same; and/or the first lead-wire layer includes a plurality of first trace leads, and the layer structure included by the first trace leads and the layer structure included by the first leads are the same.

The chip packaging unit includes three cases. In the first case, the first lead-wire layer includes a plurality of first traces, at this moment, the layer structure included by the first traces and the layer structure included by the first leads are the same. As an example, the first traces may be of a single-layer structure or a multilayer structure, which may specifically refer to the above description on the layer structure of the first leads, and is not discussed further herein. In the second case, the first lead-wire layer includes a plurality of first trace leads, and the layer structure included by the first trace leads and the layer structure included by the first leads are the same. As an example, the first traces may be of a single-layer structure or a multilayer structure, which may specifically refer to the above description on the layer structure of the first leads, and is not discussed further herein. In the third case, the first lead-wire layer includes a plurality of first traces and a plurality of first trace leads, and the first traces and the first trace leads may be of a single-layer structure or a multilayer structure, which may specifically refer to the above description on the layer structure of the first leads, and is not discussed further herein.

In some embodiments, the chip packaging unit further includes one or more lead-wire units, and the lead-wire units are disposed between the lead layer and the flexible substrate. Each of the lead-wire units includes a first lead-wire layer and a first organic layer, and the first organic layer covers the first lead-wire layer.

The first lead-wire layer includes a plurality of first traces, each of the first traces includes a plurality of conductive layers arranged in layer configuration, and each of the first leads includes one conductive layer; and/or the first lead-wire layer includes a plurality of first trace leads, each of the first trace leads includes a plurality of conductive layers arranged in layer configuration, and each of the first leads includes one conductive layer.

The chip packaging unit includes three cases. In the first case, the first lead-wire layer includes a plurality of first traces, each of the first traces includes a plurality of conductive layers arranged in layer configuration, and each of the first leads includes one conductive layer. As an example, each of the first traces includes a titanium conductive layer, an aluminum conductive layer and a titanium conductive layer that are arranged in layer configuration, and each of the first leads includes a copper conductive layer. In the second case, the first lead-wire layer includes a plurality of first trace leads, each of the first trace leads includes a plurality of conductive layers arranged in layer configuration, and each of the first leads includes one conductive layer. As an example, each of the first trace leads includes a titanium conductive layer, an aluminum conductive layer and a titanium conductive layer that are arranged in layer configuration, and each of the first leads includes a copper conductive layer. In the third case, the first lead-wire layer includes a plurality of first traces and a plurality of first trace leads, each of the first traces and each of the first trace leads include a plurality of conductive layers arranged in layer configuration, and each of the first leads includes one conductive layer. As an example, each of the first traces and each of the first trace leads include a titanium conductive layer, an aluminum conductive layer and a titanium conductive layer that are arranged in layer configuration, and each of the first leads includes a copper conductive layer.

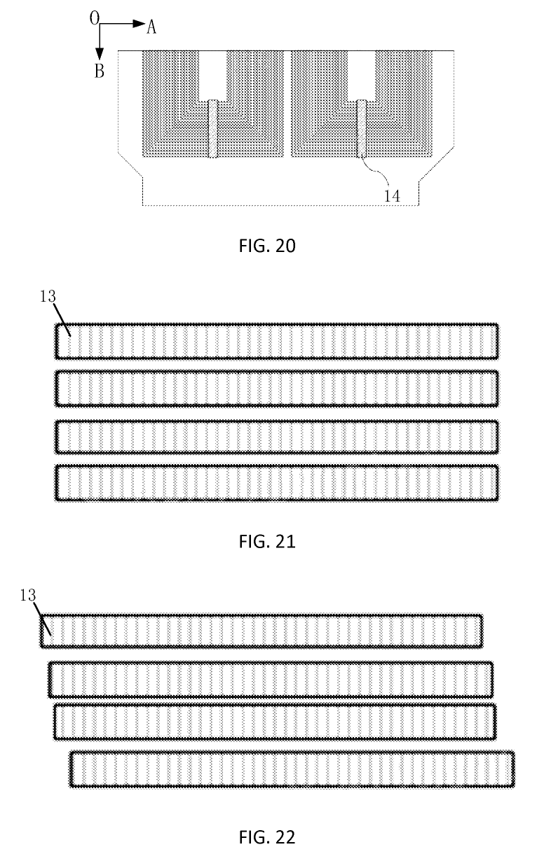

As restrained by the current factors such as silicon-wafer fabrication and cutting, usually the transverse dimension of a single IC (chip) can merely reach at most approximately 32mm, and it is difficult to export more signal lines. In the present application, the display device includes at least one chip packaging unit, and the quantity of the chip packaging units may be selected according to the size of the product. If the display device includes a plurality of chip packaging units, the modes of arranging the chips included by the chip packaging units are not limited. As an example, the chips 14 may be arranged horizontally in the direction OA as shown in FIG. 19. Alternatively, the chips 14 may be arranged vertically in the direction OB as shown in FIG. 20. Alternatively, some of chips are arranged horizontally, and some of chips are arranged vertically, which is not limited herein.

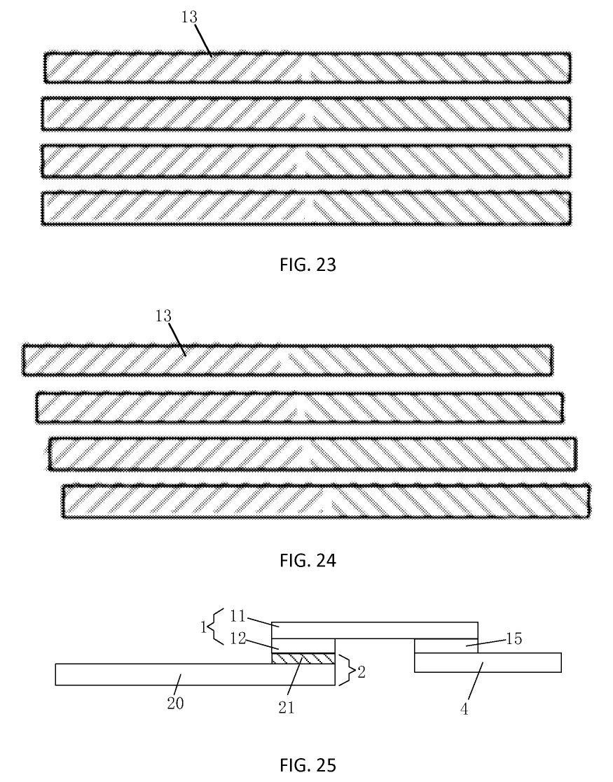

In addition, the sizes of the chips are restricted, and the modes of arranging the plurality of leads in the chip packaging units also influence the quantity of the output channels. Optionally, the plurality of first leads are arranged in an array. As an example, the plurality of first leads may be arranged in a plurality of rows, for example, in 2 rows, 3 rows, 4 rows (as shown in FIGS. 21-24) or 5 rows. The directions of the arrangement of the plurality of first leads in each of the rows and the directions of the arrangement of the plurality of rows are not limited. As an example, the plurality of rows may be arranged vertically as shown in FIG. 21, or arranged obliquely as shown in FIG. 22. In each of the rows, the first leads may be arranged vertically as shown in FIGS. 21 and 22, or arranged obliquely as shown in FIGS. 23 and 24, thereby a reverse-V-shaped arrangement is formed. The total length of the plurality of first leads may be 60mm, 68mm, 70mm, 127mm or higher, which may specifically be regulated according to the length of the panel.

In one or more embodiments, the lead layer further includes a plurality of second leads 15 shown in FIGS. 8 and 25, and the plurality of second leads 15 are disposed at one side of the flexible substrate. Referring to FIG. 25, the display device further includes a driving board 4, and the plurality of second leads 15 are bonding-connected to the driving board 4.

Herein the driving board may be a PCB (Printed Circuit Board) circuit board, and may also be an FPC (Flexible Printed Circuit) circuit board. In order to further reduce the border frame, the latter may be selected.

Optionally, in order to simplify the process and reduce the cost, the second leads are disposed in the same layer as the first leads. The layer structures included by the second leads and the first leads are the same. As an example, the second leads may be of a single-layer structure or a multilayer structure, which may specifically refer to the above description on the layer structure of the first leads, and is not discussed further herein.

Optionally, the chip packaging unit further includes a chip (IC) shown in FIG. 8, and the first leads 13 and the second leads 15 are electrically connected to the chip 14. Because the quantity of the second leads bonding-connected to the driving board is less than the quantity of the first leads bonding-connected to the display panel, the excessive second leads may also be bonded to the display panel, thereby the output channels are further increased, and the room is saved at a same time. In order to protect the chips, a packaging layer may be disposed, for example, a resin layer.

In one or more embodiments, the display panel further includes an active area connected to the non-active area. The length in a predetermined direction of the side of the chip packaging component that is bonded to the display panel, the length in the predetermined direction of the bonding part of the display panel and the length in the predetermined direction of the active area of the display panel are equal.

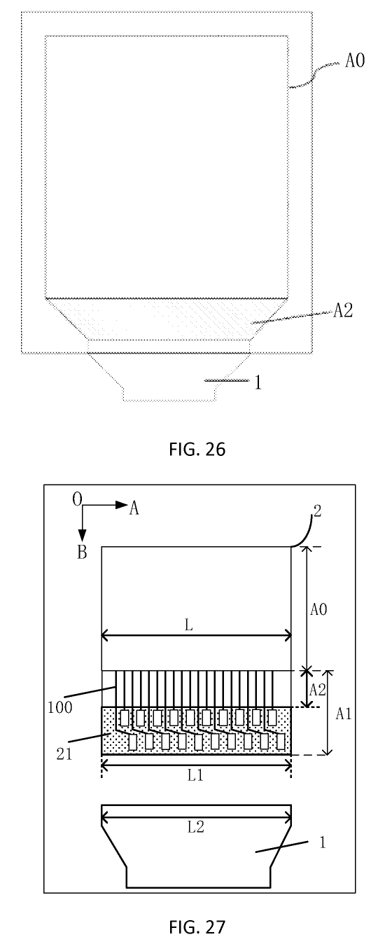

In the related art, the size of the COFs using the PI-based is restricted. When the display panel is bonded to a COF, in order to match the display panel with the size of the COF, it is required to dispose within the non-active area a sector-shaped lead-wire region (Fanout region) A2 shown in FIG. 26, the lead wires are collected within a certain region, and subsequently connected to the bonding part. In order to ensure equal-resistance wiring, the lead wires within the lead-wire region are arranged in a π shape and so on, which results in a large occupied room and thus a large border frame. However, the present application uses a glass base to form the chip packaging component, the sizes are not restricted. Referring to FIG. 27, the length L2 in a predetermined direction (the direction OA shown in FIG. 27) of the side of the chip packaging component that is bonded to the display panel, the length L1 in the predetermined direction (the direction OA shown in FIG. 27) of the bonding part of the display panel and the length L in the predetermined direction (the direction OA shown in FIG. 27) of the active area A0 of the display panel are equal. Accordingly, the lead wires 100 of the display panel can be exported directly in the direction (the direction OB shown in FIG. 27) perpendicular to the predetermined direction, and electrically connected to the bonding part, which does not require to dispose the equal-resistance wiring, thereby the border frame is reduced to the largest extent, to facilitate the formation of ultra-narrow-border-frame display products.

The “one embodiment”, “an embodiment” or “one or more embodiments” as used herein means that particular features, structures or characteristics described with reference to an embodiment are included in at least one embodiment of the present application. Moreover, it should be noted that here an example using the wording “in an embodiment” does not necessarily refer to the same embodiment.

The description provided herein describes many concrete details. However, it can be understood that the embodiments of the present application may be implemented without those concrete details. In some of the embodiments, well-known processes, structures and techniques are not described in detail, so as not to affect the understanding of the description.

Finally, it should be noted that the above embodiments are merely intended to explain the technical solutions of the present application, and not to limit them. Although the present application is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present application.

1. A chip-on-film including a chip bonding region and a panel bonding region spaced apart from each other, wherein the chip-on-film comprises:
a substrate;
one or more wiring layers, the plurality of wiring layers being stacked in a direction perpendicular to the substrate, each wiring layer comprising a plurality of through leads spaced apart from each other; and
a lead layer disposed on a side of all of the wiring layers facing away from the substrate, the lead layer comprising a plurality of third leads located in the chip bonding region, the plurality of third leads being arranged in an array along a first direction and a second direction, respectively, the first direction and the second direction intersecting each other;
wherein the third leads are connected to the panel bonding region via the through leads, and orthographic projections of the through leads on the substrate overlap with orthographic projections of lead gaps in the chip bonding region on the substrate, each lead gap being a gap between two adjacent third leads arranged along the first direction.

2. The chip-on-film according to claim 1, wherein the plurality of third leads are divided into a plurality of lead rows, each of the lead rows comprises a plurality of the third leads arranged along the first direction, the plurality of lead rows are arranged along the second direction;
the plurality of lead rows comprise a first lead row and a second lead row, the second lead row is located between the first lead row and the panel bonding region, and in the orthographic projection on the substrate, the through leads connected to the third leads in the first lead row overlap with lead gaps in the second lead row.

3. The chip-on-film according to claim 1, wherein the plurality of third leads are divided into a plurality of lead rows, each lead row comprising a plurality of the third leads arranged along the first direction, the plurality of lead rows being arranged along the second direction, and the third leads in two adjacent lead rows are aligned along the first direction.

4. The chip-on-film according to claim 3, wherein the plurality of third leads arranged along the second direction comprise a first sub-lead and a second sub-lead, the second sub-lead is located between the first sub-lead and the panel bonding region, the through lead connected to the first sub-lead is a first through lead, and the through lead connected to the second sub-lead is a second through lead;
in the orthographic projection on the substrate, the lead gaps overlapping with the second through lead also overlap with the first through lead.

5. The chip-on-film according to claim 3, wherein a plurality of lead gaps in a same lead row comprise a first lead gap and a second lead gap, and in the orthographic projection on the substrate, a number of the through leads overlapping with the first lead gap is equal to a number of the through leads overlapping with the second lead gap.

6. The chip-on-film according to claim 1, wherein the plurality of third leads are divided into a plurality of lead rows, each of the lead rows comprises a plurality of the third leads arranged along the first direction, the plurality of lead rows are arranged along the second direction, and the third leads in two adjacent lead rows are staggered along the first direction.

7. The chip-on-film according to claim 6, wherein the plurality of lead rows comprise a third lead row and a fourth lead row, the fourth lead row being located between the third lead row and the panel bonding region;
the plurality of through leads comprise a third through lead and a fourth through lead, and in the orthographic projection on the substrate, the third through lead and the fourth through lead overlap with a same lead gap in the third lead row, and the third through lead and the fourth through lead respectively overlap with different lead gaps in the fourth lead row.

8. The chip-on-film according to claim 6, wherein a plurality of lead gaps in a same lead row comprise a third lead gap and a fourth lead gap, and in the orthographic projection on the substrate, a number of the through leads overlapping with the third lead gap is less than or equal to a number of the through leads overlapping with the fourth lead gap.

9. The chip-on-film according to claim 8, wherein in the orthographic projection on the substrate, the number of the through leads overlapping with the third lead gap is less than the number of the through leads overlapping with the fourth lead gap; and
the wiring layer further comprises a dummy lead, the dummy lead is disposed spaced apart from the through leads and the third leads, respectively, and in the orthographic projection on the substrate, the dummy lead overlaps with the third lead gap, and a total number of the dummy lead and the through leads overlapping with the third lead gap is equal to the number of the through leads overlapping with the fourth lead gap.

10. The chip-on-film according to claim 1, wherein the chip-on-film comprises a plurality of the wiring layers, and in the orthographic projection on the substrate, two adjacent through leads that overlap with a same lead gap are disposed in different layers.

11. The chip-on-film according to claim 2, wherein in the orthographic projection on the substrate, the lead gaps in both the first lead row and the second lead row overlap with the through leads, and a number of the through leads overlapping with the lead gaps in the first lead row is less than a number of the through leads overlapping with the lead gaps in the second lead row.

12. The chip-on-film according to claim 2, wherein along the first direction, a width of the lead gaps in the second lead row is greater than or equal to a width of the lead gaps in the first lead row.

13. The chip-on-film according to claim 1, wherein the lead layer further comprises a bypass lead, the bypass lead being disposed spaced apart from the third leads, and an orthographic projection of the bypass lead on the substrate does not overlap with an orthographic projection of the lead gaps on the substrate.

14. The chip-on-film according to claim 1, wherein the through lead comprises third line segments and fourth line segments alternately connected, the third line segments extend along the second direction, and an extension direction of the fourth line segments intersects both the first direction and the second direction, respectively.

15. The chip-on-film according to claim 1, wherein in a case where two ends of the third line segment are each connected to one fourth line segment, the two fourth line segments connected to the same third line segment have different extension directions.

16. The chip-on-film according to claim 1, wherein a thickness of the lead layer is greater than a thickness of the wiring layer.

17. A display module, comprising:
a display panel including a non-display area, the non-display area comprising a bonding portion; and
the chip-on-film according to claim 1, the panel bonding region of the chip-on-film is bonded to the bonding portion.

18. The display module according to claim 17, wherein the chip-on-film further comprises a driving board bonding region, the driving board bonding region and the panel bonding region being disposed opposite to each other along the second direction on two sides of the chip bonding region;
the display module further comprises at least one of:
a chip, bonded at least to the third leads in the chip bonding region; and
a driving board, bonded to the driving board bonding region.

19. The display module according to claim 18, wherein the driving board comprises: a flexible circuit board and a rigid circuit board, the flexible circuit board is connected between the driving board bonding region and the rigid circuit board.

20. A display device, comprising the chip-on-film according to claim 1.
